(19) United States
(12) Patent Application Publication
(10) Pub. No.: US 2025/0254991 A1
(43) Pub. Date: Aug. 7, 2025

(54) FILLER CELL, SEMICONDUCTOR DEVICE, AND LOGIC CIRCUIT

(71) Applicant: REALTEK SEMICONDUCTOR CORP., Hsinchu (TW)

(72) Inventor: Chan-Yuan Chang, Hsinchu (TW)

(73) Assignee: REALTEK SEMICONDUCTOR CORP., Hsinchu (TW)

(21) Appl. No.: 18/889,987

(22) Filed: Sep. 19, 2024

(30) Foreign Application Priority Data
Feb. 5, 2024 (TW) 113104558

(51) Int. Cl. H01L 27/118

(52) U.S. Cl. CPC H10D 84/907; H10D 84/974

(57) ABSTRACT

A filler cell, a semiconductor device, and a logic circuit are provided. The filler cell includes two dummy polysilicon layers and a threshold voltage layer. The dummy polysilicon layers are arranged at intervals in a first direction. The threshold voltage layer is below the dummy polysilicon layers, and the two opposite sides of the threshold voltage layer in the first direction extend in a second direction and are respectively aligned with center points of the dummy polysilicon layers. The two opposite sides of the threshold voltage layer in the second direction are respectively aligned with the two opposite sides of each of the dummy polysilicon layers in the second direction. The first direction is perpendicular to the second direction. The semiconductor device includes a plurality of filler cells, at least one transistor cell, and another two threshold voltage layers. The logic circuit includes a plurality of semiconductor devices.

### CROSS-REFERENCE TO RELATED APPLICATION

This non-provisional application claims priority under 35 U.S.C. § 119 (a) to patent application No. 113104558 filed in Taiwan, R.O.C. on Feb. 5, 2024, the entire contents of which are hereby incorporated by reference.

### BACKGROUND

### Technical Field

The present disclosure relates to semiconductor processes and transistor layouts, and particularly relates to a filler cell, a semiconductor device, and a logic circuit.

### Related Art

With the progress of semiconductor process technology, transistors have been developed from planar transistors with a two-dimensional (2D) structure to stereoscopic transistors with a three-dimensional (3D) structure. For example, field-effect transistors (FETs) are developed from the 2D metal-oxide-semiconductor field-effect transistors (MOSFETs) in the past to the 3D Fin field-effect transistors (FinFETs) nowadays, and low-voltage elements made from the FinFETs have different threshold voltages. However, the logic sharing technology adapted for the MOSFETs in the past is no longer suitable for the advanced FinFETs, which results in a poor area utilization of the logic circuit composed of the low-voltage elements, thereby causing a higher cost of the logic circuit.

### SUMMARY

In order to address the issue(s) mentioned above, the inventors provide a filler cell, a semiconductor device, and a logic circuit. In the semiconductor device, the filler cell with a smaller area is arranged between the adjacent two transistor cells, allowing a plurality of transistor cells to share a dummy polysilicon layer so as to effectively decrease the area of the logic circuit (e.g., improving the rate of the area utilization) to reduce the manufacturing cost of the logic circuit.

In some embodiments, a filler cell comprises two dummy polysilicon layers and a first threshold voltage layer. The two dummy polysilicon layers are arranged at intervals in a first direction. The first threshold voltage layer is below the two dummy polysilicon layers. Two opposite sides of the first threshold voltage layer in the first direction extend in a second direction and are respectively aligned with center points of the two dummy polysilicon layers, and two opposite sides of the first threshold voltage layer in the second direction are respectively aligned with two opposite sides of each of the two dummy polysilicon layers in the second direction. The first direction is perpendicular to the second direction.

In some embodiments, the filler cell further comprises two second threshold voltage layers. The two second threshold voltage layers are arranged at intervals in the second direction. Two adjacent sides of each of the two second threshold voltage layers extend in the first direction and are respectively aligned with the two opposite sides of the first threshold voltage layer in the second direction, and two opposite sides of each of the two second threshold voltage layers in the first direction are respectively aligned with the two opposite sides of the first threshold voltage layer in the first direction.

In some embodiments, the first threshold voltage layer has a dopant with a single concentration, and the first threshold voltage layer and each of the two second threshold voltage layers have dopants with different polarities.

In some embodiments, the dopant for the first threshold voltage layer is a Group III element or a Group V element, and the dopant for each of the two second threshold voltage layers is a Group III element or a Group V element.

In some embodiments, a concentration of the dopant for each of the two second threshold voltage layers is higher than a concentration of the dopant for the first threshold voltage layer.

In some embodiments, the first threshold voltage layer is divided into two doped regions in the second direction, a partition border between the two doped regions is on an interval area between the two dummy polysilicon layers, and the two doped regions have dopants with different concentrations.

In some embodiments, the dopant for each of the two doped regions is a Group III element or a Group V element, and the dopant for each of the two second threshold voltage layers is a Group III element or a Group V element.

In some embodiments, a concentration of the dopant for each of the two second threshold voltage layers is higher than a concentration of the dopant for the two doping regions.

In some embodiments, a semiconductor device comprises a plurality of filler cells, at least one transistor cell, and two fifth threshold voltage layers. The at least one transistor cell is between two adjacent filler cells of the plurality of filler cells, and the at least one transistor cell comprises a third threshold voltage layer, an oxide layer, a polysilicon layer, and two fourth threshold voltage layers. Two opposite sides of the third threshold voltage layer in the first direction extend in the second direction and are respectively aligned with a first side of the first threshold voltage layer for one of the two adjacent filler cells and a second side of the first threshold voltage layer for the other one of the two adjacent filler cells, and two opposite sides of the third threshold voltage layer in the second direction are respectively aligned with two opposite sides of each of the two adjacent filler cells in the second direction. The oxide layer is on the third threshold voltage layer. A range of an area of the oxide layer is less than a range of an area of the third threshold voltage layer, and a center point of the oxide layer is aligned with a center point of the third threshold voltage layer. The polysilicon layer is on the oxide layer. Lengths of the two opposite sides of the polysilicon layer in the first direction are equal to lengths of the two opposite sides of the third threshold voltage layer in the first direction, and the two opposite sides of the polysilicon layer in the second direction are respectively aligned with two sides of the third threshold voltage layer in the second direction. The two fourth threshold voltage layers are arranged at intervals in the second direction. Two adjacent sides of each of the two fourth threshold voltage layers extend in the first direction and are respectively aligned with the two opposite sides of the third threshold voltage layer in the second direction, the two opposite sides of each of the two fourth threshold voltage layers in the first direction are respectively aligned with the two opposite sides of the third threshold voltage layer in the first direction, and the third threshold voltage layer and each of the two fourth threshold voltage layers have dopants with different polarities. A first side of one of the two fifth threshold voltage layers in the first direction is aligned with a second side of the first one of the plurality of filler cells in the first direction, and a second side of the other one of the two fifth threshold voltage layers in the first direction is aligned with a first side of the last one of the plurality of filler cells in the first direction. The first direction is perpendicular to the second direction, and the dummy polysilicon layer of each of the plurality of filler cells adjacent to the at least one transistor cell is on the third threshold voltage layer of the at least one transistor cell.

In some embodiments, the first threshold voltage layer has a dopant with a single concentration, and the concentration of the dopant for the first threshold voltage layer is equal to a concentration of a dopant for the adjacent third threshold voltage layer.

In some embodiments, the dopant for the first threshold voltage layer is a Group III element or a Group V element, the dopant for each of the two second threshold voltage layers is a Group III element or a Group V element, the dopant for the third threshold voltage layer is a Group III element or a Group V element, a dopant for each of the two fourth threshold voltage layers is a Group III element or a Group V element, and a dopant for each of the two fifth threshold voltage layers is a Group III element or a Group V element.

In some embodiments, a concentration of the dopant for each of the two second threshold voltage layers, a concentration of the dopant for each of the two fourth threshold voltage layers, and a concentration of the dopant for each of the two fifth threshold voltage layers are equal. The concentration of the dopant for each of the two second threshold voltage layers, the concentration of the dopant for each of the two fourth threshold voltage layers, and the concentration of the dopant for each of the two fifth threshold voltage layers are higher than the concentration of the dopant for the first threshold voltage layer and the concentration of the dopant for the third threshold voltage layer.

In some embodiments, the first threshold voltage layer is divided into two doped regions in the second direction, a partition border between the two doped regions is on an interval area between the two dummy polysilicon layers, and the two doped regions have dopants with different concentrations.

In some embodiments, a dopant for each of the two doped regions is a Group III element or a Group V element, the dopant for each of the two second threshold voltage layers is a Group III element or a Group V element, the dopant for the third threshold voltage layer is a Group III element or a Group V element, a dopant for each of the two fourth threshold voltage layers is a Group III element or a Group V element, and a dopant for each of the two fifth threshold voltage layers is a Group III element or a Group V element.

In some embodiments, a concentration of the dopant for each of the two second threshold voltage layers, a concentration of the dopant for each of the two fourth threshold voltage layers, and a concentration of the dopant for each of the two fifth threshold voltage layers are equal. The concentration of the dopant for each of the two second threshold voltage layers, the concentration of the dopant for each of the two fourth threshold voltage layers, and the concentration of the dopant for each of the two fifth threshold voltage layers are higher than a concentration of the dopant for each of the two doped regions and the concentration of the dopant for the third threshold voltage layer.

In some embodiments, a logic circuit comprises a plurality of semiconductor devices of any embodiment, and the plurality of semiconductor devices is adjacently and sequentially arranged in the second direction. For two adjacent semiconductor devices in the plurality of semiconductor devices, the polarity of the dopant for the first threshold voltage layer of one of the two semiconductor devices is opposite to the polarity of the dopant for the first threshold voltage layer of the other one of the two semiconductor devices, the polarity of the dopant for the second threshold voltage layers of one of the two semiconductor devices is opposite to the polarity of the dopant for the second threshold voltage layers of the other one of the two semiconductor devices, the polarity of the dopant for the third threshold voltage layer of one of the two semiconductor devices is opposite to the polarity of the dopant for third threshold voltage layer of the other one of the two semiconductor devices, the polarity of the dopant for the fourth threshold voltage layers of one of the two semiconductor devices is opposite to the polarity of the dopant for the fourth threshold voltage layers of the other one of the two semiconductor devices, and the polarity of the dopant for the fifth threshold voltage layers of one of the two semiconductor devices is opposite to the polarity of the dopant for the fifth threshold voltage layers of the other one of the two semiconductor devices.

In conclusion, according to one or some embodiments, the semiconductor device can couple a plurality of transistor cells via filler cells with smaller areas to make research and development (RD) engineers design devices with specific functions at a lower cost and a higher rate of an area utilization. In addition, the RD engineers can couple a plurality of semiconductor devices together to implement a larger logic circuit (for example, a super large scale integration) so as to design circuits with complex functions.

### BRIEF DESCRIPTION OF DRAWINGS

The instant disclosure will become more fully understood from the detailed description given herein below for illustration only, and therefore not limitative of the instant disclosure, wherein:

FIG. 1 illustrates a layout schematic view of a first embodiment of a filler cell;

FIG. 2 illustrates a schematic perspective view of some embodiments of the filler cell shown in FIG. 1;

FIG. 3 illustrates a schematic perspective cross-sectional view of the filler cell along the line 3-3 shown in FIG. 2;

FIG. 4 illustrates a layout schematic view of a second embodiment of a filler cell;

FIG. 5 illustrates a schematic perspective view of some embodiments of the filler cell shown in FIG. 4;

FIG. 6 illustrates a schematic perspective cross-sectional view of the filler cell along the line 6-6 shown in FIG. 5;

FIG. 7 illustrates a layout schematic view of a first embodiment of a semiconductor device;

FIG. 8 illustrates a layout schematic view of a second embodiment of a semiconductor device;

FIG. 9 illustrates a layout schematic view of some embodiments of a transistor cell shown in FIG. 7 and FIG. 8;

FIG. 10 illustrates a schematic perspective view of some embodiments of the semiconductor device shown in FIG. 7;

FIG. 11 illustrates a schematic perspective cross-sectional view of the semiconductor device along the line 11-11 shown in FIG. 10; and

FIG. 12 illustrates a layout schematic view of an embodiment of a logic circuit.

### DETAILED DESCRIPTION

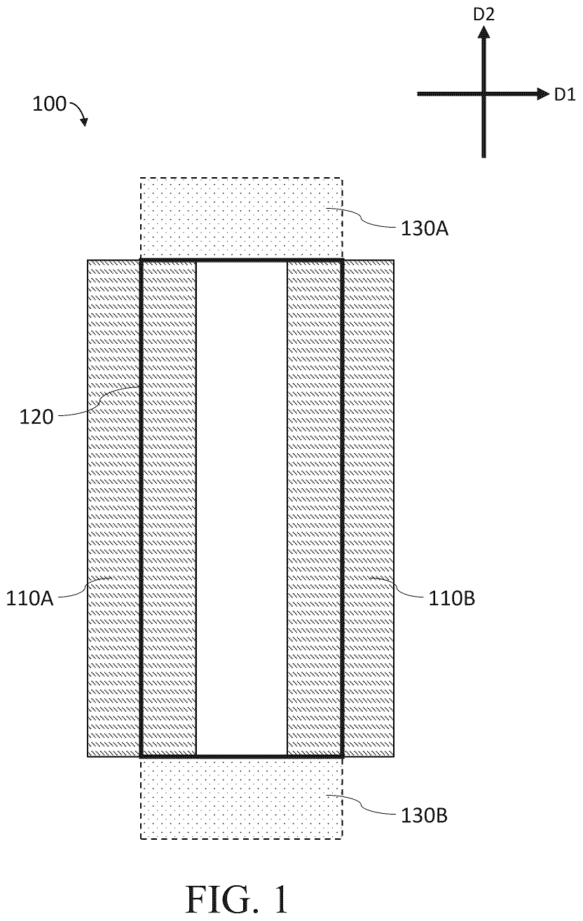

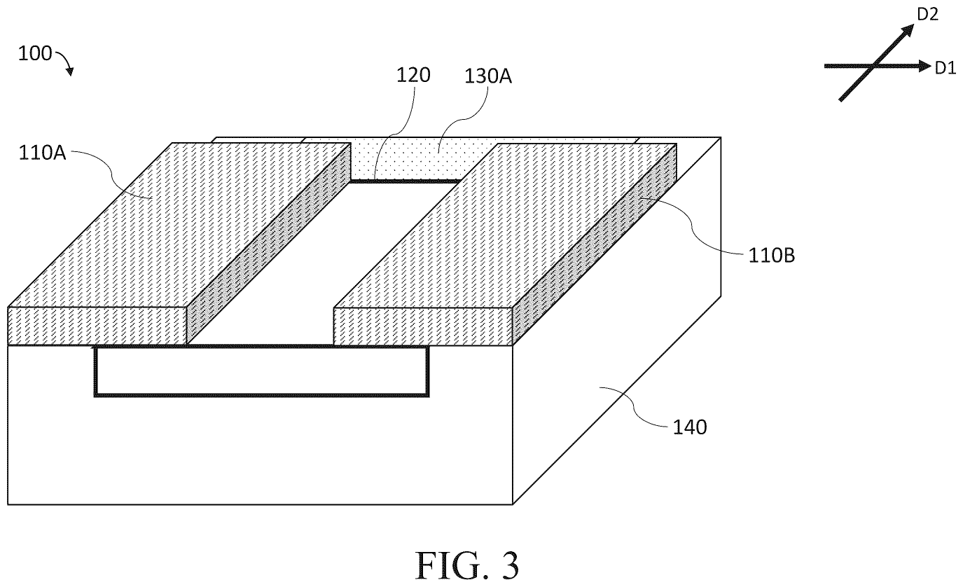

Please refer to FIG. 1 to FIG. 3. A filler cell 100 comprises two dummy polysilicon layers 110A, 110B and a threshold voltage layer 120 (hereinafter referred as a first threshold voltage layer 120), and the dummy polysilicon layers 110A, 110B are arranged at intervals in a first direction D1.

The first threshold voltage layer 120 is below the dummy polysilicon layers 110A, 110B. Two opposite sides of the first threshold voltage layer 120 in the first direction D1 extend in a second direction D2 and are respectively aligned with center points of the dummy polysilicon layers 110A, 110B, and two opposite sides of the first threshold voltage layer 120 in the second direction D2 are respectively aligned with two opposite sides of each of the dummy polysilicon layers 110A, 110B in the second direction D2. In other words, in some embodiments, the two opposite sides of the first threshold voltage layer 120 in the first direction D1 are respectively adjacent to the dummy polysilicon layer 110A and the dummy polysilicon layer 110B, and lengths of the two opposite sides of the first threshold voltage layer 120 in the first direction D1 are equal to a length of the two opposite sides of the dummy polysilicon layer 110A (or the dummy polysilicon layer 110B) in the first direction D1. In some embodiments, the first direction D1 is perpendicular to the second direction D2.

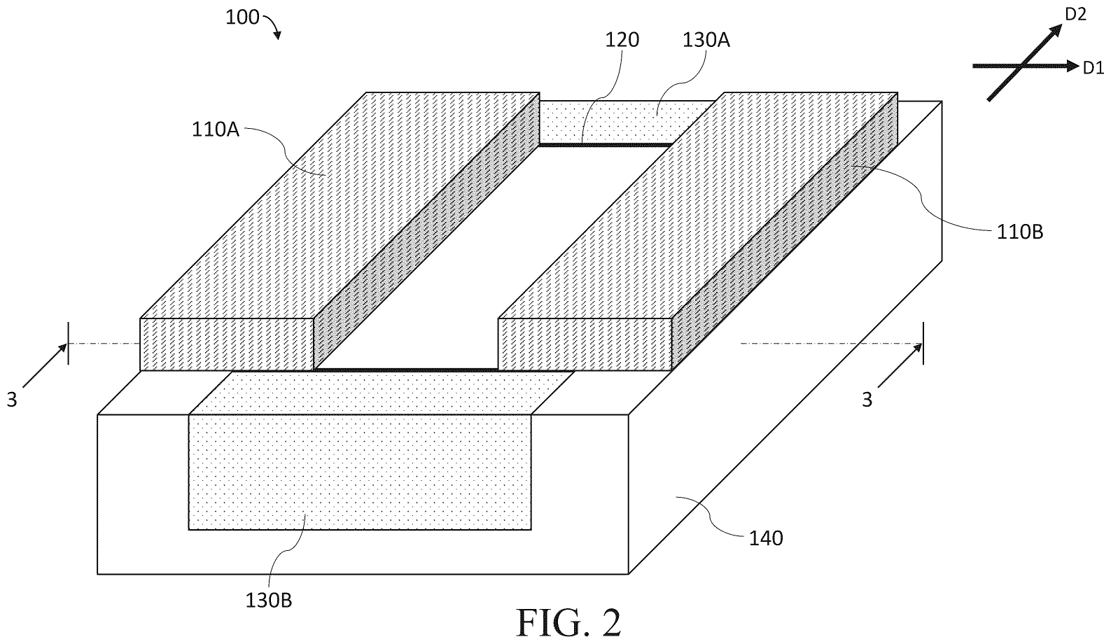

In some embodiments, the filler cell 100 further comprises another two threshold voltage layers 130A, 130B (hereinafter referred as second threshold voltage layers 130A, 130B). As shown in FIG. 1 and FIG. 2, the second threshold voltage layers 130A, 130B are arranged at intervals in the second direction D2 Two adjacent sides of each of the second threshold voltage layers 130A, 130B extend in the first direction D1 and are respectively aligned with the two opposite sides of the first threshold voltage layer 120 in the second direction D2, and two opposite sides of each second threshold voltage layers 130A, 130B in the first direction D1 are respectively aligned with the two opposite sides of the first threshold voltage layer 120 in the first direction D1. In other words, in some embodiments, lengths of the two adjacent sides of the second threshold voltage layers 130A, 130B are equal to a length of the two opposite sides of the first threshold voltage layer 120 in the second direction D2.

In some embodiments, the filler cell 100 further comprises a substrate layer 140. The dummy polysilicon layers 110A, 110B and the first threshold voltage layer 120 (and the second threshold voltage layer 130A, 130B) are arranged on the substrate layer 140 in the aforementioned configuration relationship.

In some embodiments, the first threshold voltage layer 120 has a dopant with a single concentration, and the first threshold voltage layer 120 and the second threshold voltage layer 130A, 130B have dopants with different polarities. In some embodiments, the dopant for the first threshold voltage layer is a Group III element or a Group V element, and the dopant for the second threshold voltage layer 130A/130B is a Group III element or a Group V element. In other words, in some embodiments, when the dopant of the first threshold voltage layer 120 is a Group III element, the dopant of the second threshold voltage layer 130A/130B is a Group V element; while when the dopant of the first threshold voltage layer 120 is a Group V element, the dopant of the second threshold voltage layer 130A/130B is a Group III element.

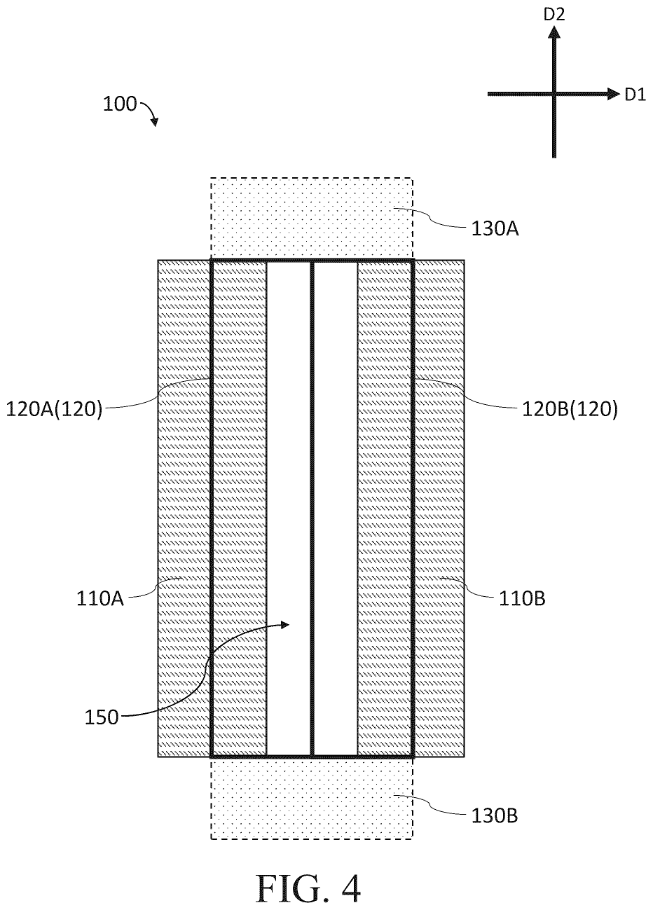

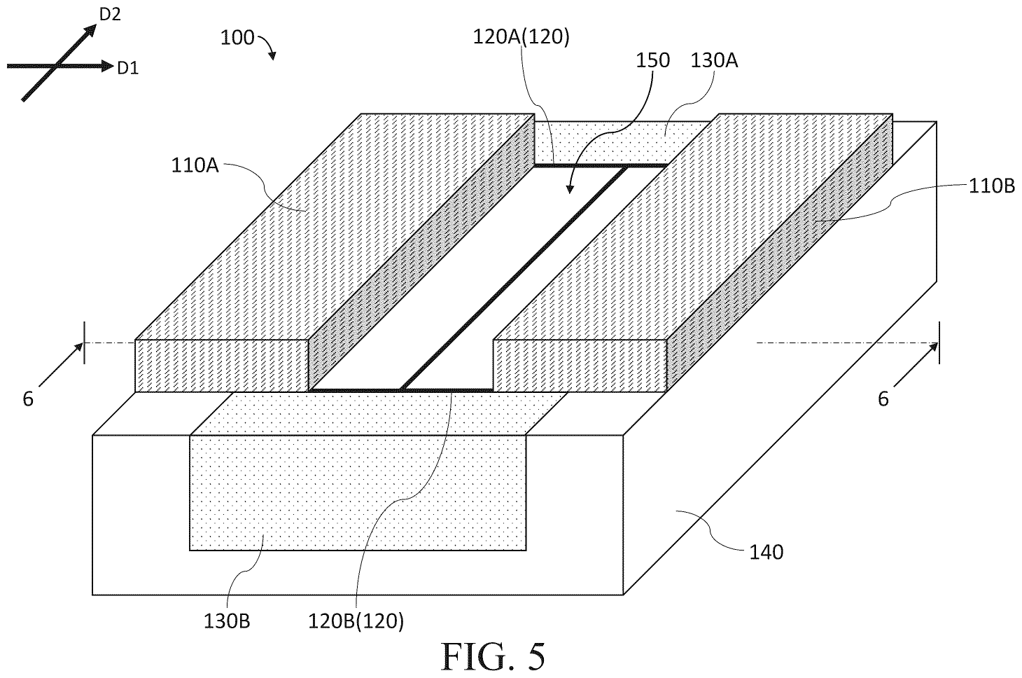

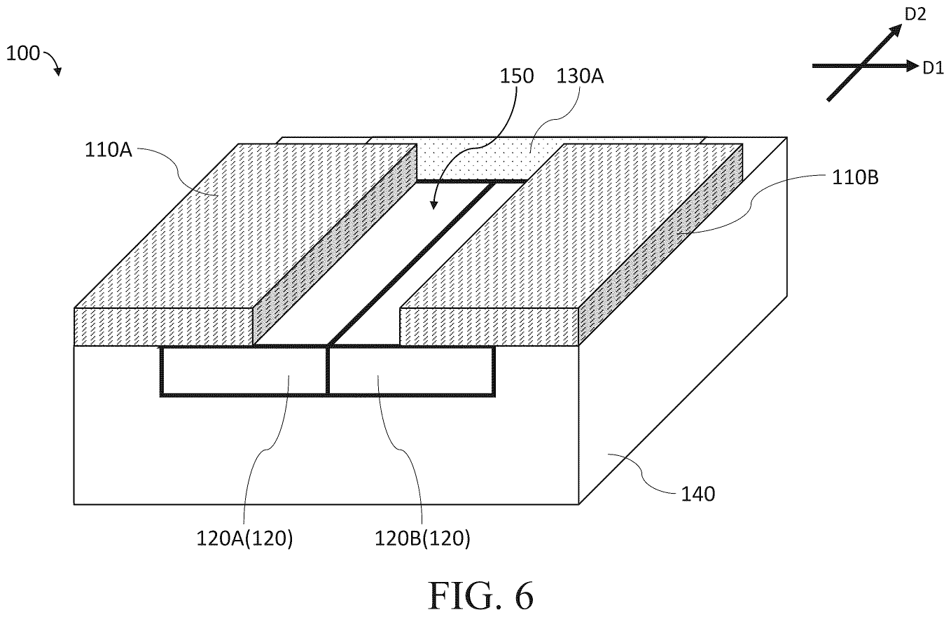

In some other embodiments, the first threshold voltage layer 120 may be designed to have dopants with different concentrations. Please refer to FIG. 4 to FIG. 6, the first threshold voltage layer 120 of the filler cell 100 is divided into two doped regions 120A, 120B in the second direction D2, a partition border between the doped regions 120A, 120B is on an interval area 150 between the dummy polysilicon layers 110A, 110B, and the doped regions 120A, 120B respectively have dopants with different concentrations. In some embodiments, the interval area 150 corresponds to the substrate layer 140.

In some embodiments, the doped region 120A is on the dummy polysilicon layer 110A and the substrate layer 140, and the doped region 120B is on the dummy polysilicon layer 110B and the substrate layer 140.

Please refer to FIG. 1 to FIG. 11. In some embodiments, the filler cell 100 of any aforementioned embodiment may be adapted to a semiconductor device SD. In other words, the semiconductor device SD at least comprises the filler cell 100 of any aforementioned embodiment. In some embodiments, the semiconductor device SD comprises a plurality of filler cells 100 and at least one transistor cell 200. In some embodiments, the plurality of filler cells 100 is sequentially arranged at intervals in the first direction D1, and the at least one transistor cell 200 is between two adjacent filler cells 100 of the plurality of filler cells 100.

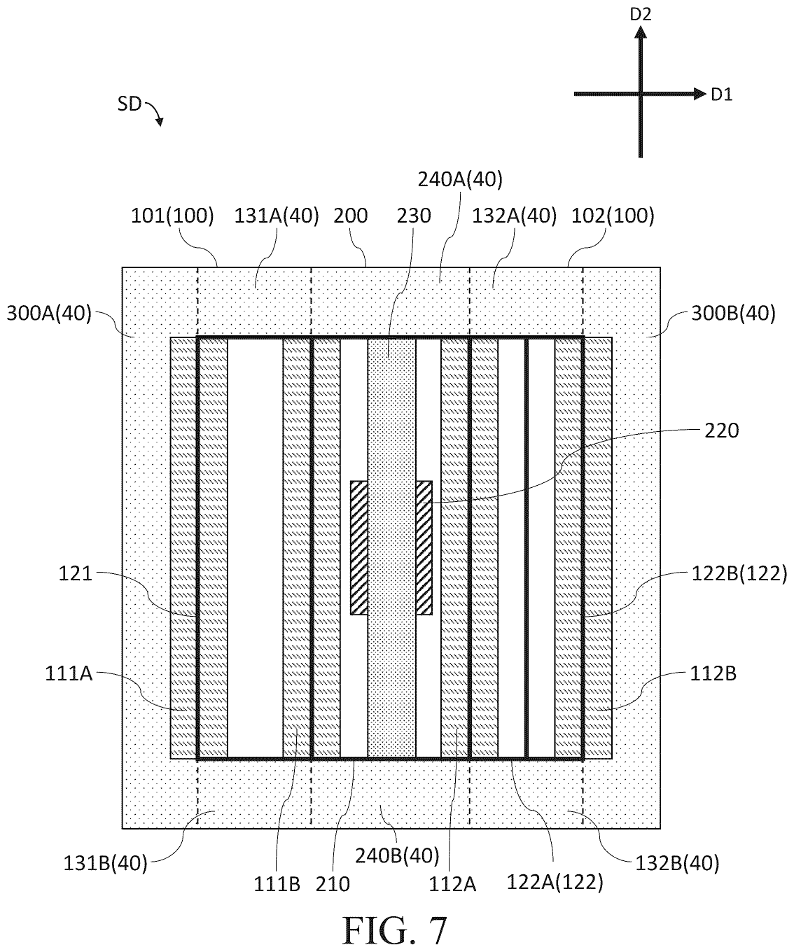

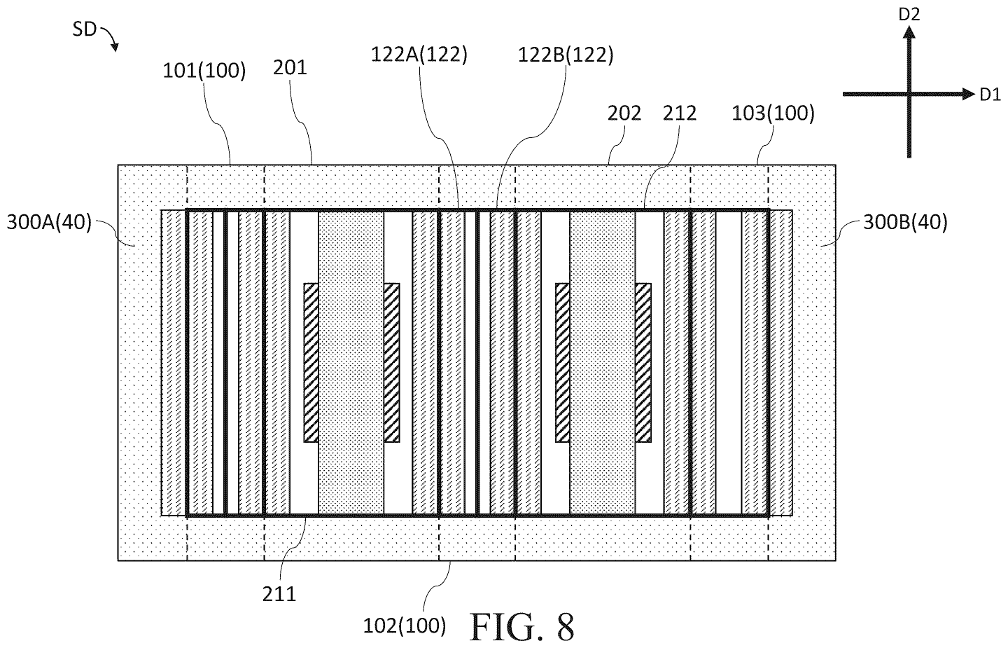

Take FIG. 7 for example, in the present embodiment, the semiconductor device SD comprises two filler cells 101, 102 and a transistor cell 200. In some embodiments, the filler cells 101, 102 are sequentially arranged at intervals in the first direction D1, and the transistor cell 200 is between the filler cells 101, 102. Further take FIG. 8 for example, in the present embodiments, the semiconductor device SD comprises three filler cells 101, 102, 103 and two transistor cells 201, 202. In some embodiments, the filler cells 101, 102, 103 are sequentially arranged at intervals in the first direction D1, the transistor cell 201 is between the filler cells 101, 102, and the transistor cell 202 is between the filler cells 102, 103.

In other words, in some embodiments, the filler cell 100 is configured to be a medium for the transistor cell 200 to be coupled to other elements or cells. For example, the transistor cell 200 may be coupled to another transistor cell 200 via the filler cell 100.

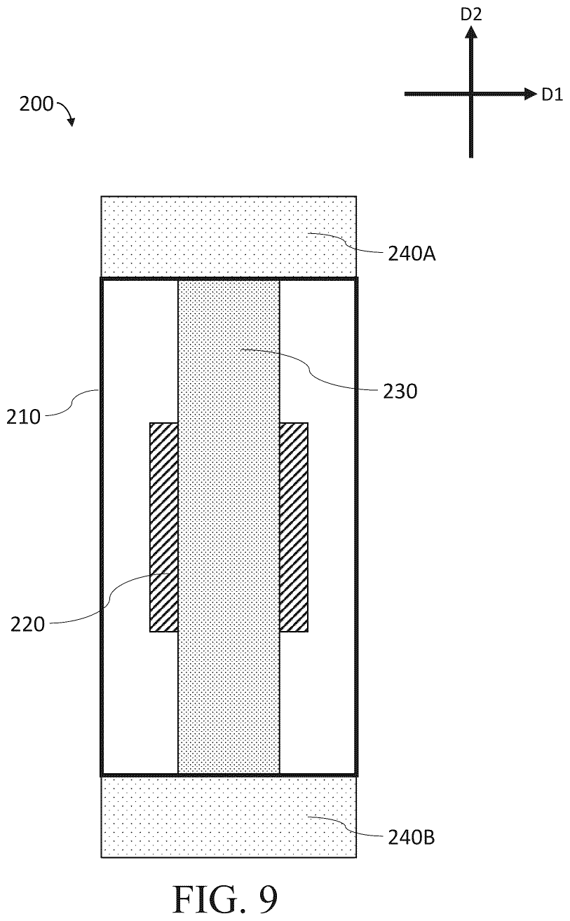

As shown in FIG. 9, in some embodiments, the transistor cell 200 comprises a threshold voltage layer 210 (hereinafter referred as a third threshold voltage layer 210), an oxide layer 220, a polysilicon layer 230, and another two threshold voltage layers 240A, 240B (hereinafter referred as fourth threshold voltage layers 240A, 240B). In some embodiments, two opposite sides of the third threshold voltage layer 210 in the first direction D1 extend in the second direction D2 and are respectively aligned with a first side of the first threshold voltage layer 121 for one of the two adjacent filler cells 101, 102 (for example, the filler cell 101) and a second side of the first threshold voltage layer 122 for the other one of the two adjacent filler cells 101, 102 (for example, the filler cell 102). Also, two opposite sides of the third threshold voltage layer 210 in the second direction D2 are respectively aligned with two opposite sides of each of the two adjacent filler cells 101, 102 in the second direction D2. In other words, in some embodiments, the two opposite sides of the third threshold voltage layer 210 in the first direction D1 are respectively adjacent to the adjacent filler cells 101, 102, and lengths of the two opposite sides of the third threshold voltage layer 210 in the first direction D1 are equal to lengths of two opposite sides of the filler cell 101 (or the filler cell 102) in the first direction D1.

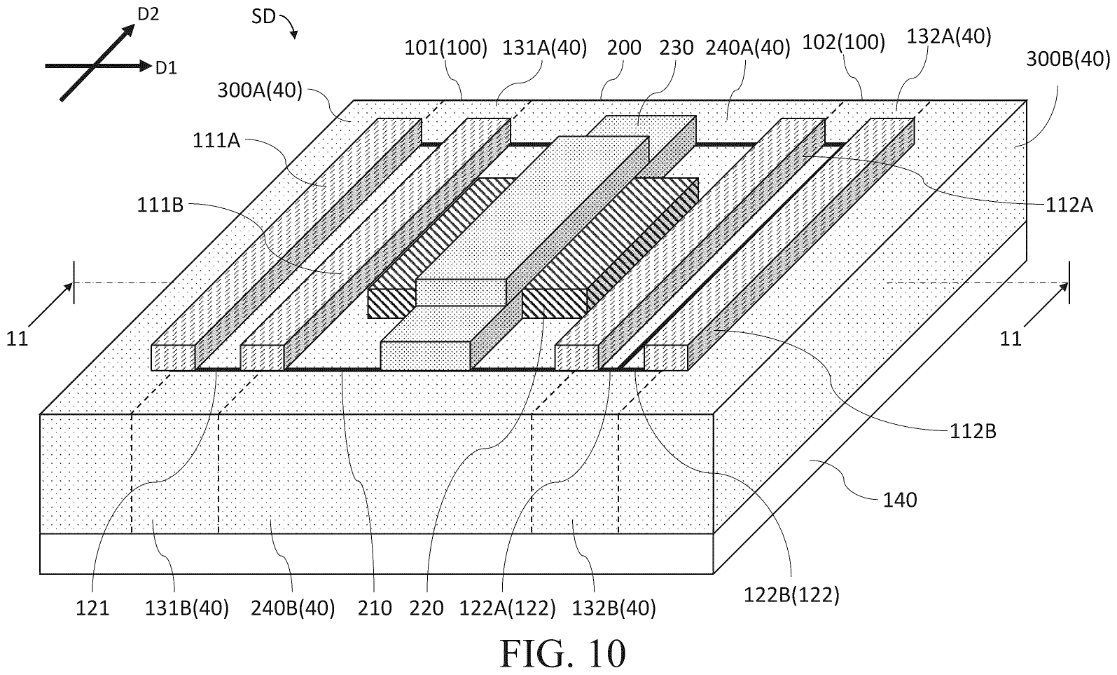

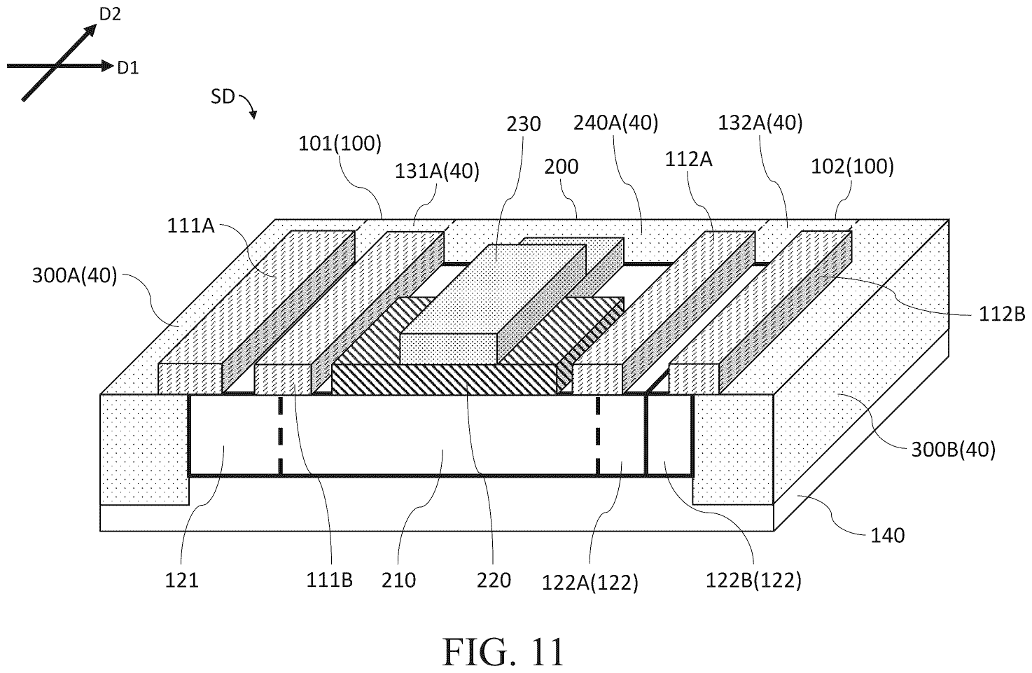

In some embodiments, the oxide layer 220 is on the third threshold voltage layer 210 (as shown in FIG. 11). A range of an area of the oxide layer 220 is less than a range of an area of the third threshold voltage layer 210, and a center point of the oxide layer 220 is aligned with a center point of the third threshold voltage layer 210. In other words, in some embodiments, a length of any side of the oxide layer 220 is less than a length of the corresponding side of the third threshold voltage layer 210 so as to make the oxide layer 220 just cover a part of the third threshold voltage layer 210 (as shown in FIG. 10). In some embodiments, the polysilicon layer 230 is on the oxide layer 220 (as shown in FIG. 11). Lengths of the two opposite sides of the polysilicon layer 230 in the first direction D1 are equal to lengths of the two opposite sides of the third threshold voltage layer 210 in the first direction D1, and the two sides of the polysilicon layer 230 in the second direction D2 are respectively aligned with two sides of the third threshold voltage layer 210 in the second direction D2. It should be noticed that, in some embodiments, the lengths of the two sides of the polysilicon layer 230 in the second direction D2 are less than lengths of the two sides of the oxide layer 220 in the second direction D2 (as shown in FIG. 10).

In some embodiments, the fourth threshold voltage layers 240A, 240B are arranged at intervals in the second direction D2. Two adjacent sides of each of the two fourth threshold voltage layers 240A, 240B extend in the first direction D1 and are respectively aligned with the two opposite sides of the third threshold voltage layer 210 in the second direction D2, and the two opposite sides of each of the two fourth threshold voltage layers 240A, 240B in the first direction D1 are respectively aligned with the two opposite sides of the third threshold voltage layer 210 in the first direction D1. In some embodiments, the third threshold voltage layer 210 and each of the fourth threshold voltage layers 240A, 240B have dopants with different polarities. In other words, in some embodiments, lengths of the adjacent two sides of the fourth threshold voltage layers 240A, 240B are equal to the opposite two sides of the third threshold voltage layer 210 in the second direction D2.

In some embodiments, the dummy polysilicon layers 110A, 110B of each of the filler cells 100 adjacent to the at least one transistor cell 200 is on the third threshold voltage layer 210 of the at least one transistor cell 200. Take FIG. 11 for example, in the present embodiment, the dummy polysilicon layers 111A, 111B of the filler cell 101 and the dummy polysilicon layers 112A, 112B of the filler cell 102 are both on the third threshold voltage layer 210 of the transistor cell 200.

In some embodiments, the semiconductor device SD further comprises two threshold voltage layer 300A, 300B (hereinafter referred as fifth threshold voltage layers 300A, 300B). A first side of one of the two fifth threshold voltage layers 300A, 300B (for example, the fifth threshold voltage layer 300A) in the first direction D1 is aligned with a second side of the first one of the plurality of filler cells 101, 102 in the first direction D1, and a second side of the other one of the two fifth threshold voltage layers 300A, 300B (for example, the fifth threshold voltage layer 300B) in the first direction D1 is aligned with a first side of the last one of the plurality of filler cells 101, 102 in the first direction D1. In other words, in some embodiments, the transistor cell 200 is coupled to the fifth threshold voltage layers 300A, 300B respectively via the filler cells 101, 102.

In some embodiments, when the first threshold voltage layer 120 of the filler cell 100 only has a dopant with a single concentration, the filler cell 100 can only couple two transistor cells 200 which have the third threshold voltage layers 210 having the dopant with the same concentration together. In some other embodiments, when the first threshold voltage layer 120 of the filler cell 100 has two doped regions 120A, 120B having dopants with different concentrations, the filler cell 100 can couple two transistor cells 200 which have the third threshold voltage layers 210 having the dopant with different concentrations together. In other words, in some embodiments, a concentration of the dopant for the first threshold voltage layer 120 in the filler cell 100 is equal to a concentration of the dopant for the third threshold voltage layer 210 in the transistor cell 200 adjacent to the filler cell 100. Or, in some embodiments, the concentrations of the dopants for the doped regions 120A, 120B of the filler cell 100 are respectively equal to the concentration of the dopant for the third threshold voltage layer 210 in the transistor cell 200 adjacent to the doped regions 120A, 120B of the filler cell 100, and the concentrations of the dopants for the doped regions 122A, 122B of the filler cell 100 are respectively equal to the concentration of the dopant for the third threshold voltage layer 210 in the transistor cell 200 adjacent to the doped regions 122A, 122B of the filler cell 100.

Take FIG. 8 for example, in the present embodiment, the concentration of the dopant for the doped regions 122A in the first threshold voltage layer 122 of the filler cell 102 is equal to the concentration of the dopant for the third threshold voltage layer 211 in the transistor cell 201, and the concentration of the dopant for the doped regions 122B in the first threshold voltage layer 122 of the filler cell 102 is equal to the concentration of the dopant for the third threshold voltage layer 212 in the transistor cell 202. Therefore, the filler cell 102 can be configured to couple the transistor cells 201, 202 together. It should be noticed that, in some embodiments, regardless the first threshold voltage layer 120 of the filler cell 100 has the dopant with the single concentration (for example, the filler cell 101 shown in FIG. 7 and the filler cell 103 shown in FIG. 8) or has the dopants with different concentrations (for example, the filler cell 102 shown in FIG. 7 and the filler cell 101 shown in FIG. 8), the filler cell 100 can couple the transistor cell 200 and the fifth threshold voltage layer 300A together or can couple the transistor cell 200 and the fifth threshold voltage layer 300B together (as shown in FIG. 7 and FIG. 8).

As shown in FIG. 7, FIG. 8, and FIG. 10, in some embodiments, the fifth threshold voltage layers 300A, 300B are configured as reversed U-shape structures, and the space of the reverse U-shape structures in each of the fifth threshold voltage layers 300A, 300B is configured to accommodate the filler cells 101, 102. Therefore, the two second threshold voltage layers 131A, 131B of the filler cells 101, the two second threshold voltage layers 132A, 132B of the filler cells 102, the two fourth threshold voltage layers 240A, 240B of the transistor cell 200, and the two fifth threshold voltage layers 300A, 300B together form a guard ring 40 to surround the plurality of filler cells 101, 102 and the transistor cell 200. In some embodiments, the guard ring 40 is configured to protect the transistor cell 200 from being influenced by other signals or elements and thus generating problems. Herein, the guard ring 40 is known to a person having ordinary skills in the art and will not be described in detail.

In some embodiments, a concentration of a dopant for the guard ring 40 needs to be higher than concentrations of dopants in the elements that is protected by the guard ring 40, so that the guard ring 40 can achieve a protection effect. Therefore, in some embodiments, the concentration of the dopant for each of the second threshold voltage layers 130A, 130B is higher than the concentration of the dopant for the first threshold voltage layer 120. Or, in some embodiments, the concentrations of the dopants for the second threshold voltage layers 130A, 130B are higher than the concentrations of the dopants for the doped regions 120A, 120B in the first threshold voltage layer 120.

In addition, in some embodiments, the concentrations of the dopants for the two second threshold voltage layers 130A, 130B of the plurality of filler cells 100, the concentrations of the dopants for the two fourth threshold voltage layers 240A, 240B of the at least one transistor cell 200, and the concentrations of the dopants for the two fifth threshold voltage layers 300A, 300B of the at least one transistor cell 200 are equal to make sure that the protection effects of all areas in the guard ring 40 are equal.

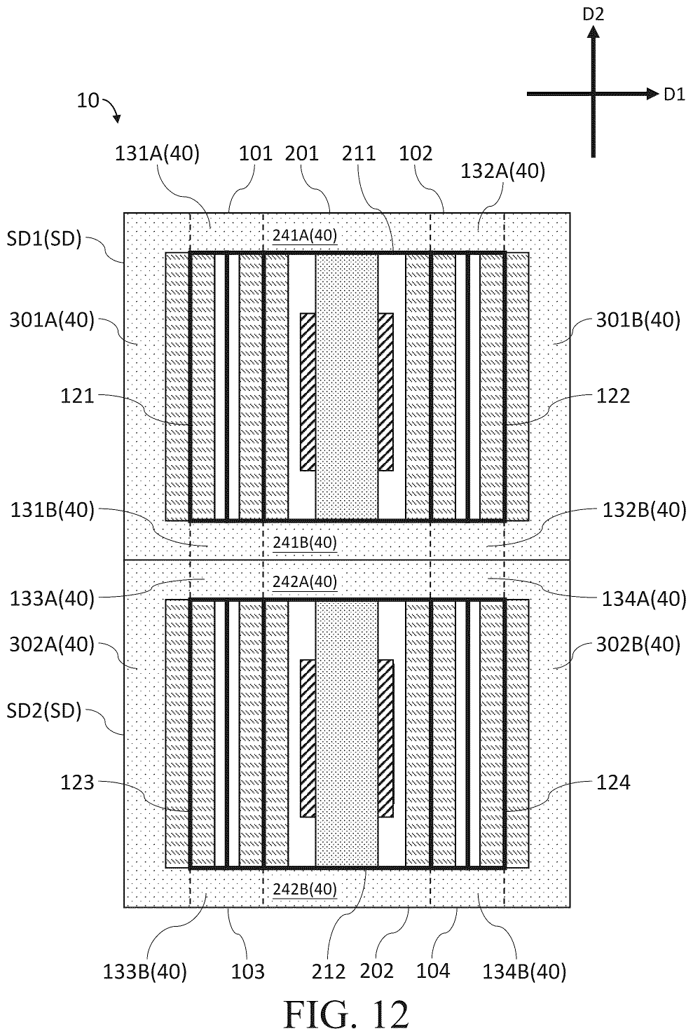

Please refer to FIG. 1 to FIG. 12, in some embodiments, the semiconductor device SD of any aforementioned embodiment may be adapted to a logic circuit 10. In other words, in some embodiments, the logic circuit 10 at least comprises the semiconductor device SD of any aforementioned embodiment. In some embodiments, the logic circuit 10 comprises a plurality of semiconductor devices SD, and the plurality of semiconductor devices SD is adjacently and sequentially arranged in the second direction D2. Take FIG. 12 for example, in the present embodiment, the logic circuit 10 comprises two semiconductor devices SD1, SD2. In some embodiments, the semiconductor device SD1 comprises two filler cells 101, 102 and a transistor cell 201, and the semiconductor device SD2 comprises two filler cell 103, 104 and a transistor cell 202.

In some embodiments, for two adjacent semiconductor devices SD in the plurality of semiconductor devices SD, polarity of the dopant for the first threshold voltage layer 120 of one of the two semiconductor devices SD is opposite to the polarity of the dopant for the first threshold voltage layer 120 of the other one of the two semiconductor devices SD, the polarity of the dopant for the second threshold voltage layers 130A, 130B of one of the two semiconductor devices SD is opposite to the polarity of the dopant for the second threshold voltage layers 130A, 130B of the other one of the two semiconductor devices SD, the polarity of the dopant for the third threshold voltage layer 210 of one of the two semiconductor devices SD is opposite to the polarity of the dopant for third threshold voltage layer 210 of the other one of the two semiconductor devices SD, the polarity of the dopant for the fourth threshold voltage layers 240A, 240B of one of the two semiconductor devices SD is opposite to the polarity of the dopant for the fourth threshold voltage layers 240A, 240B of the other one of the two semiconductor devices SD, and the polarity of the dopant for the fifth threshold voltage layers 300A, 300B of one of the two semiconductor devices SD is opposite to the polarity of the dopant for the fifth threshold voltage layers 300A, 300B of the other one of the two semiconductor devices SD. In other words, in some embodiments, the threshold voltage layers in the corresponding cells of the semiconductor devices SD1, SD2 have dopants with opposite polarities.

In some embodiments, the logic circuit 10 shown in FIG. 12 is, for example but not limited to, a complementary metal-oxide-semiconductor (CMOS) element, where the semiconductor device SD1 is a P-type MOSFET (PMOS), and the semiconductor device SD2 is an N-type MOSFET (NMOS). Herein, the dopant for the first threshold voltage layer 121/122 of the filler cell 101/102 in the semiconductor device SD1 is a Group III element, and the dopant for the first threshold voltage layer 123/124 of the filler cell 103/104 in the semiconductor device SD2 is a Group V element. The dopant for the two second threshold voltage layer 131A, 131B/132A, 132B of the filler cell 101/102 in the semiconductor device SD1 is a Group V element, and the dopant for the two second threshold voltage layer 133A, 133B/134A, 134B of the filler cell 103/104 in the semiconductor device SD2 is a Group III element. The dopant for the third threshold voltage layer 211 of the transistor cell 201 in the semiconductor device SD1 is a Group III element, and the dopant for the third threshold voltage layer 212 of the transistor cell 202 in the semiconductor device SD2 is a Group V element. The dopants for the fourth threshold voltage layers 241A, 241B are Group V elements, and the dopants for the fourth threshold voltage layers 242A, 242B are Group III elements. The dopants for the fifth threshold voltage layers 301A, 2301B are Group V elements, and the dopants for the fifth threshold voltage layers 302A, 302B are Group III elements.

In some embodiments, the Group III element may be boron (B), aluminum (Al), gallium (Ga), indium (In), or a mixture comprising at least two selected from the group consisting of boron, aluminum, gallium, and indium. In some embodiments, the Group V element may be phosphor (P), arsenic (As), antimony (Te), or a mixture comprising at least two selected from the group of phosphor, arsenic, and antimony.

In some embodiments, the transistor cells 200 may be various types of semiconductor elements, such as but not limited bipolar junction transistor (BJT), MOSFET, FinFET, or gate-all-around field-effect transistor (GAA-FET).

In some embodiments, the oxide layer 220 may be a dielectric layer made of a material with insulating properties, such as but not limited to silicon dioxide (SiO₂), hafnium dioxide (HfO₂), or zirconium dioxide (ZrO₂).

In conclusion, according to one or some embodiments, the semiconductor device SD can couple a plurality of transistor cells 200 via filler cells 100 with smaller areas to make research and development (RD) engineers design devices with specific functions at a lower cost and a higher rate of an area utilization. In addition, the RD engineers can couple a plurality of semiconductor devices SD together to implement a larger logic circuit 10 (for example, a super large scale integration) so as to design circuits with complex functions.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A filler cell comprising:
two dummy polysilicon layers arranged at intervals in a first direction; and
a first threshold voltage layer below the two dummy polysilicon layers, wherein two opposite sides of the first threshold voltage layer in the first direction extend in a second direction and are respectively aligned with center points of the two dummy polysilicon layers, and two opposite sides of the first threshold voltage layer in the second direction are respectively aligned with two opposite sides of each of the two dummy polysilicon layers in the second direction;
wherein, the first direction is perpendicular to the second direction.

2. The filler cell according to claim 1, further comprising:
two second threshold voltage layers arranged at intervals in the second direction, wherein two adjacent sides of each of the two second threshold voltage layers extend in the first direction and are respectively aligned with the two opposite sides of the first threshold voltage layer in the second direction, and two opposite sides of each of the two second threshold voltage layers in the first direction are respectively aligned with the two opposite sides of the first threshold voltage layer in the first direction.

3. The filler cell according to claim 2, wherein the first threshold voltage layer has a dopant with a single concentration, and the first threshold voltage layer and each of the two second threshold voltage layers have dopants with different polarities.

4. The filler cell according to claim 3, wherein the dopant for the first threshold voltage layer is a Group III element or a Group V element, and the dopant for each of the two second threshold voltage layers is a Group III element or a Group V element.

5. The filler cell according to claim 4, wherein a concentration of the dopant for each of the two second threshold voltage layers is higher than a concentration of the dopant for the first threshold voltage layer.

6. The filler cell according to claim 2, wherein the first threshold voltage layer is divided into two doped regions in the second direction, a partition border between the two doped regions is on an interval area between the two dummy polysilicon layers, and the two doped regions have dopants with different concentrations.

7. The filler cell according to claim 6, wherein the dopant for each of the two doped regions is a Group III element or a Group V element, and the dopant for each of the two second threshold voltage layers is a Group III element or a Group V element.

8. The filler cell according to claim 7, wherein a concentration of the dopant for each of the two second threshold voltage layers is higher than a concentration of the dopant for the two doping regions.

9. A semiconductor device comprising:
a plurality of filler cells sequentially arranged at intervals in a first direction, wherein each of the plurality of filler cells comprises:
two dummy polysilicon layers arranged at intervals in a first direction;
a first threshold voltage layer below the two dummy polysilicon layers, wherein two opposite sides of the first threshold voltage layer in the first direction extend in a second direction and are respectively aligned with center points of the two dummy polysilicon layers, and two opposite sides of the first threshold voltage layer in the second direction are respectively aligned with two opposite sides of each of the two dummy polysilicon layers in the second direction; and
two second threshold voltage layers arranged at intervals in the second direction, wherein two adjacent sides of each of the two second threshold voltage layers extend in the first direction and are respectively aligned with the two opposite sides of the first threshold voltage layer in the second direction, two opposite sides of each of the two second threshold voltage layers in the first direction are respectively aligned with the two opposite sides of the first threshold voltage layer in the first direction, and the first threshold voltage layer and each of the two second threshold voltage layers have dopants with different polarities;
at least one transistor cell between two adjacent filler cells of the plurality of filler cells, wherein the at least one transistor cell comprises:
a third threshold voltage layer, wherein two opposite sides of the third threshold voltage layer in the first direction extend in the second direction and are respectively aligned with a first side of the first threshold voltage layer for one of the two adjacent filler cells and a second side of the first threshold voltage layer for the other one of the two adjacent filler cells, and two opposite sides of the third threshold voltage layer in the second direction are respectively aligned with two opposite sides of each of the two adjacent filler cells in the second direction;
an oxide layer on the third threshold voltage layer, wherein a range of an area of the oxide layer is less than a range of an area of the third threshold voltage layer, and a center point of the oxide layer is aligned with a center point of the third threshold voltage layer;
a polysilicon layer on the oxide layer, wherein lengths of the two opposite sides of the polysilicon layer in the first direction are equal to lengths of the two opposite sides of the third threshold voltage layer in the first direction, and the two opposite sides of the polysilicon layer in the second direction are respectively aligned with two sides of the third threshold voltage layer in the second direction; and
two fourth threshold voltage layers arranged at intervals in the second direction, wherein two adjacent sides of each of the two fourth threshold voltage layers extend in the first direction and are respectively aligned with the two opposite sides of the third threshold voltage layer in the second direction, the two opposite sides of each of the two fourth threshold voltage layers in the first direction are respectively aligned with the two opposite sides of the third threshold voltage layer in the first direction, and the third threshold voltage layer and each of the two fourth threshold voltage layers have dopants with different polarities; and
two fifth threshold voltage layers, wherein a first side of one of the two fifth threshold voltage layers in the first direction is aligned with a second side of the first one of the plurality of filler cells in the first direction, and a second side of the other one of the two fifth threshold voltage layers in the first direction is aligned with a first side of the last one of the plurality of filler cells in the first direction;
wherein, the first direction is perpendicular to the second direction;
the two dummy polysilicon layers of each of the plurality of filler cells adjacent to the at least one transistor cell is on the third threshold voltage layer of the at least one transistor cell.

10. The semiconductor device according to claim 9, wherein the first threshold voltage layer has a dopant with a single concentration, and the concentration of the dopant for the first threshold voltage layer is equal to a concentration of a dopant for the adjacent third threshold voltage layer.

11. The semiconductor device according to claim 10, wherein the dopant for the first threshold voltage layer is a Group III element or a Group V element, the dopant for each of the two second threshold voltage layers is a Group III element or a Group V element, the dopant for the third threshold voltage layer is a Group III element or a Group V element, a dopant for each of the two fourth threshold voltage layers is a Group III element or a Group V element, and a dopant for each of the two fifth threshold voltage layers is a Group III element or a Group V element.

12. The semiconductor device according to claim 11, wherein a concentration of the dopant for each of the two second threshold voltage layers, a concentration of the dopant for each of the two fourth threshold voltage layers, and a concentration of the dopant for each of the two fifth threshold voltage layers are equal;
the concentration of the dopant for each of the two second threshold voltage layers, the concentration of the dopant for each of the two fourth threshold voltage layers, and the concentration of the dopant for each of the two fifth threshold voltage layers are higher than the concentration of the dopant for the first threshold voltage layer and the concentration of the dopant for the third threshold voltage layer.

13. The semiconductor device according to claim 9, wherein the first threshold voltage layer is divided into two doped regions in the second direction, a partition border between the two doped regions is on an interval area between the two dummy polysilicon layers, and the two doped regions have dopants with different concentrations.

14. The semiconductor device according to claim 13, wherein a dopant for each of the two doped regions is a Group III element or a Group V element, the dopant for each of the two second threshold voltage layers is a Group III element or a Group V element, the dopant for the third threshold voltage layer is a Group III element or a Group V element, a dopant for each of the two fourth threshold voltage layers is a Group III element or a Group V element, and a dopant for each of the two fifth threshold voltage layers is a Group III element or a Group V element.

15. The semiconductor device according to claim 14, wherein a concentration of the dopant for each of the two second threshold voltage layers, a concentration of the dopant for each of the two fourth threshold voltage layers, and a concentration of the dopant for each of the two fifth threshold voltage layers are equal;
the concentration of the dopant for each of the two second threshold voltage layers, the concentration of the dopant for each of the two fourth threshold voltage layers, and the concentration of the dopant for each of the two fifth threshold voltage layers are higher than a concentration of the dopant for each of the two doped regions and the concentration of the dopant for the third threshold voltage layer.

16. A logic circuit comprising:
a plurality of semiconductor devices, each of the plurality of semiconductor device comprises:
a plurality of filler cells sequentially arranged at intervals in a first direction, wherein each of the plurality of filler cells comprises:
two dummy polysilicon layers arranged at intervals in a first direction;
a first threshold voltage layer below the two dummy polysilicon layers, wherein two opposite sides of the first threshold voltage layer in the first direction extend in a second direction and are respectively aligned with center points of the two dummy polysilicon layers, and two opposite sides of the first threshold voltage layer in the second direction are respectively aligned with two opposite sides of each of the two dummy polysilicon layers in the second direction; and
two second threshold voltage layers arranged at intervals in the second direction, wherein two adjacent sides of each of the two second threshold voltage layers extend in the first direction and are respectively aligned with the two opposite sides of the first threshold voltage layer in the second direction, two opposite sides of each of the two second threshold voltage layers in the first direction are respectively aligned with the two opposite sides of the first threshold voltage layer in the first direction, and the first threshold voltage layer and each of the two second threshold voltage layers have dopants with different polarities;
at least one transistor cell between two adjacent filler cells of the plurality of filler cells, wherein the at least one transistor cell comprises:
a third threshold voltage layer, wherein two opposite sides of the third threshold voltage layer in the first direction extend in the second direction and are respectively aligned with a first side of the first threshold voltage layer for one of the two adjacent filler cells and a second side of the first threshold voltage layer for the other one of the two adjacent filler cells, and two opposite sides of the third threshold voltage layer in the second direction are respectively aligned with two opposite sides of each of the two adjacent filler cells in the second direction;
an oxide layer on the third threshold voltage layer, wherein a range of an area of the oxide layer is less than a range of an area of the third threshold voltage layer, and a center point of the oxide layer is aligned with a center point of the third threshold voltage layer;
a polysilicon layer on the oxide layer, wherein lengths of the two opposite sides of the polysilicon layer in the first direction are equal to lengths of the two opposite sides of the third threshold voltage layer in the first direction, and the two opposite sides of the polysilicon layer in the second direction are respectively aligned with two sides of the third threshold voltage layer in the second direction; and
two fourth threshold voltage layers arranged at intervals in the second direction, wherein two adjacent sides of each of the two fourth threshold voltage layers extend in the first direction and are respectively aligned with the two opposite sides of the third threshold voltage layer in the second direction, the two opposite sides of each of the two fourth threshold voltage layers in the first direction are respectively aligned with the two opposite sides of the third threshold voltage layer in the first direction, and the third threshold voltage layer and each of the two fourth threshold voltage layers have dopants with different polarities; and
two fifth threshold voltage layers, wherein a first side of one of the two fifth threshold voltage layers in the first direction is aligned with a second side of the first one of the plurality of filler cells in the first direction, and a second side of the other one of the two fifth threshold voltage layers in the first direction is aligned with a first side of the last one of the plurality of filler cells in the first direction;
wherein, the dummy polysilicon layer of each of the plurality of filler cells adjacent to the at least one transistor cell is on the third threshold voltage layer of the at least one transistor cell;
wherein, the plurality of semiconductor devices is adjacently and sequentially arranged in the second direction, and the first direction is perpendicular to the second direction;
for two adjacent semiconductor devices in the plurality of semiconductor devices, the polarity of the dopant for the first threshold voltage layer of one of the two semiconductor devices is opposite to the polarity of the dopant for the first threshold voltage layer of the other one of the two semiconductor devices, the polarity of the dopant for the second threshold voltage layers of one of the two semiconductor devices is opposite to the polarity of the dopant for the second threshold voltage layers of the other one of the two semiconductor devices, the polarity of the dopant for the third threshold voltage layer of one of the two semiconductor devices is opposite to the polarity of the dopant for third threshold voltage layer of the other one of the two semiconductor devices, the polarity of the dopant for the fourth threshold voltage layers of one of the two semiconductor devices is opposite to the polarity of the dopant for the fourth threshold voltage layers of the other one of the two semiconductor devices, and the polarity of the dopant for the fifth threshold voltage layers of one of the two semiconductor devices is opposite to the polarity of the dopant for the fifth threshold voltage layers of the other one of the two semiconductor devices.
